(19) United States
(12) Patent Application Publication
(10) Pub. No.: US 2020/0064408 A1
(43) Pub. Date: Feb. 27, 2020

(54) VEHICULAR BATTERY MONITORING SYSTEM

(71) Applicants: AutoNetworks Technologies, Ltd., Yokkaichi, Mie (JP); Sumitomo Wiring Systems, Ltd., Yokkaichi, Mie (JP); Sumitomo Electric Industries, Ltd., Osaka-Shi (JP)

(72) Inventor: Shinichiro Sato, Yokkaichi, Mie (JP)

(21) Appl. No.: 16/345,960

(22) PCT Filed: Oct. 11, 2017
(86) PCT No.: PCT/JP2017/036739

§ 371 Date: Apr. 29, 2019

(30) Foreign Application Priority Data
Nov. 1, 2016 (JP) 2016-214061

(51) Int. Cl. G01R 31/382; B60L 50/50; B60R 16/023; H01M 10/48; H02J 7/02; H02J 7/00; H01M 10/44; H04Q 9/00

(52) U.S. Cl. CPC G01R 31/382; B60L 50/50; B60R 16/023; H01M 10/482; H02J 7/02; H04Q 2209/40; H02J 7/0057; H01M 10/441; H04Q 9/00; H01M 10/486; H02J 7/0021

(57) ABSTRACT

Monitoring of vehicular batteries is realized with a configuration in which the number of wires can be reduced and information can be better transmitted. A battery monitoring device includes: a detection unit configured to detect at least one of a voltage at a predetermined position of a battery installed in a vehicle and a temperature of the battery; and a wireless communication unit configured to wirelessly transmit detection information that indicates at least one of the voltage and the temperature of the battery based on a detection result of the detection unit, the detection information being wirelessly transmitted at least to a relay that has a function to relay and wirelessly transmit information to a battery ECU.

### CROSS-REFERENCE TO RELATED APPLICATIONS

This application is the U.S. national stage of PCT/JP2017/036739 filed Oct. 11, 2017, which claims priority of Japanese Patent Application No. JP 2016-214061 filed Nov. 1, 2016, the contents of which are incorporated herein.

### TECHNICAL FIELD

The present disclosure relates to a vehicular battery monitoring system.

### BACKGROUND

Conventionally, a technique for monitoring a plurality of cells that constitute a battery using a battery monitoring device has been provided. For example, JP 2015-79585A discloses a battery monitoring device provided with satellite substrates (circuit boards) that respectively correspond to a plurality of assembled batteries, each satellite substrate being provided with a monitoring IC for monitoring voltages across the cells of the corresponding assembled battery. Also, the plurality of satellite substrates are connected to each other via a coupling wire, and one of the satellite substrates is connected to a main substrate via a connecting wire.

However, since the battery monitoring device disclosed in JP 2015-79585A requires the coupling wire, which couples the satellite substrates with each other, and the connecting wire, which couples the satellite substrate and the main substrate, resulting in an increase in the number of wires, which may cause the problem that the battery monitoring device is heavy and large. Moreover, there is also the problem that, due to the increase in the number of wires, the wiring design is complicated.

As a method for solving the aforementioned problems, the inventor of the present application has arrived at a configuration in which information generated by a battery monitoring device is transmitted to the outside via wireless communication. According to this configuration, it is possible to realize a battery monitoring device or a battery monitoring system for which the number of wires can be reduced.

However, when information generated by the battery monitoring device is transmitted to the outside via wireless communication in this way, there may be cases where wireless communication is not likely to be performed well, such as a case where a device to which the information is to be transmitted is located far away or a case where there is an obstacle on the way to the device to which the information is to be transmitted.

The present disclosure was made in view of the aforementioned circumstances, and it is an object thereof to provide a vehicular battery monitoring system for which the number of wires can be reduced and with which information can be better transmitted.

### SUMMARY

According to the present disclosure, a battery monitoring system includes a battery monitoring device provided with a detection unit configured to detect at least one of a voltage at a predetermined position of a battery installed in a vehicle and a temperature of the battery. A wireless communication unit configured to wirelessly transmit detection information that indicates at least one of the voltage and the temperature of the battery based on a detection result of the detection unit. A relay provided with a receiving unit configured to receive the detection information transmitted from the wireless communication unit of the battery monitoring device. A transmitting unit configured to wirelessly transmit the detection information received by the receiving unit to an external device, wherein the battery monitoring device and the relay are arranged in a metal housing in which the battery and the external device are housed, part of the metal housing is arranged as an obstacle portion between the battery monitoring device and the external device, and the relay is arranged in a positional relationship such that there is a space without the obstacle portion between the battery monitoring device and the relay, and there is a space without the obstacle portion between the external device and the relay.

### Advantageous Effects of Disclosure

According to the present disclosure, since detection information (information indicating at least one of a voltage and a temperature of the battery) obtained based on a detection result of the detection unit can be transmitted via wireless communication, it is possible to effectively reduce the number of wires. Furthermore, when the detection information is transmitted to the external device, the detection information can at least be relayed by the relay and then transmitted to the external device, and thus the information can be better transmitted as long as the external device is arranged at a position at which wireless transmission is possible from the relay.

Furthermore, it is possible to well perform wireless communication in an environment in which a wireless communication medium is likely to be impaired when wireless transmission is performed directly from the battery monitoring device to the external device.

Moreover, a metal housing can be used to prevent external impact or external interference of radio waves or the like, and in the metal housing, the number of wires is reliably reduced and communication between the battery monitoring device and the external device is likely to be performed well.

### BRIEF DESCRIPTION OF DRAWINGS

FIG. 1 is a block diagram schematically illustrating an example of an onboard power supply system provided with a battery monitoring system according to Embodiment 1.

FIG. 2 is a block diagram specifically illustrating the battery monitoring system of Embodiment 1 and a battery.

FIG. 3(A) is a plan view partially illustrating, in a simplified manner, a configuration in which a battery monitoring device of Embodiment 1 is attached to the battery, and FIG. 3(B) is a front view thereof.

FIG. 4 is a flowchart illustrating an example of a flow of control that is executed by a battery ECU.

FIG. 5 is a flowchart illustrating an example of a flow of control that is executed by the battery monitoring device.

FIG. 6 is a diagram schematically illustrating a configuration in which the battery monitoring system of Embodiment 1 is housed together with the battery in a metal housing.

### DETAILED DESCRIPTION OF PREFERRED EMBODIMENTS

Hereinafter, preferred embodiments of the disclosure will be described.

In the battery monitoring system according to the present disclosure, the receiving unit of the relay may function to, if predetermined instruction information is wirelessly transmitted from the external device, receive this instruction information. The transmitting unit of the relay may function to wirelessly transmit the instruction information upon the instruction information being received by the receiving unit. The battery monitoring device may include a control unit configured to perform control that corresponds to an instruction given from the outside. The wireless communication unit may function to receive the instruction information when the instruction information is wirelessly transmitted from the transmitting unit. The control unit may function to perform control that corresponds to the instruction information upon the instruction information being received by the wireless communication unit.

According to the above-described configuration, it is possible to realize a battery monitoring system in which the battery monitoring device can perform control that corresponds to an instruction from an external device, with a configuration in which the number of wires can be reduced and information can be well transmitted.

In the battery monitoring system according to the present disclosure, the receiving unit of the relay may function to, if predetermined notification instruction information is wirelessly transmitted from the external device, receive this notification instruction information. The transmitting unit of the relay may function to wirelessly transmit the notification instruction information upon the notification instruction information being received by the receiving unit. When the notification instruction information is received by the wireless communication unit, the control unit may cause the wireless communication unit to wirelessly transmit the detection information indicating at least one of the voltage and the temperature of the battery to the relay.

According to the above-described configuration, it is possible to realize a battery monitoring system in which information detected by the battery monitoring device (detection information indicating at least one of a voltage and a temperature of a battery) can be transmitted to an external device in accordance with an instruction from the external device, with a configuration in which the number of wires can be reduced and information can be well transmitted.

In the battery monitoring system according to the present disclosure, the receiving unit of the relay may function to, if predetermined cell balance instruction information is wirelessly transmitted from the external device, receive this cell balance instruction information. The transmitting unit of the relay may function to wirelessly transmit the cell balance instruction information upon the cell balance instruction information being received by the receiving unit. The detection unit may detect, with respect to the battery in which a plurality of battery cells are connected to each other, voltage information that specifies inter-terminal voltages of the battery cells. When the cell balance instruction information is received by the wireless communication unit, the control unit may cause the plurality of battery cells to charge or discharge so that the inter-terminal voltages of the battery cells are equalized, based on detection results of the detection unit.

According to the above-described configuration, it is possible to realize a battery monitoring system in which the battery monitoring device can perform cell balance control to equalize inter-terminal voltages of a plurality of battery cells in accordance with an instruction from an external device, with a configuration in which the number of wires can be reduced and information can be well transmitted.

The battery monitoring system according to the present disclosure may include a plurality of battery monitoring devices. The relay may function to receive items of information wirelessly transmitted from the plurality of battery monitoring devices, and wirelessly transmit the received items of information to the external device.

According to the above-described configuration, it is possible to realize a system in which a plurality of battery monitoring devices can communicate with a common external device, with a configuration in which the number of wires can be reduced and information can be well transmitted.

Particularly, if a plurality of battery monitoring devices are arranged in a distributed manner, and wires are provided so that communication is possible between the respective battery monitoring devices and the external device, the larger number of wires are required, and thus an increase in size and weight is inevitable. In contrast thereto, according to the above-described configuration, when the plurality of battery monitoring devices communicate with the common external device, it is possible to significantly reduce the number of wires, and thus larger effects of reductions in size and weight can be achieved.

The battery monitoring system according to the present disclosure may include the external device.

According to the above-described configuration, it is possible to realize a battery monitoring system in which the number of wires can be reduced and information can be well transmitted, with the external device included therein.

### Embodiment 1

Hereinafter, Embodiment 1 of the present disclosure will be described.

First, an overview of a vehicular power supply system 100, which is an application example of the present disclosure, will be described.

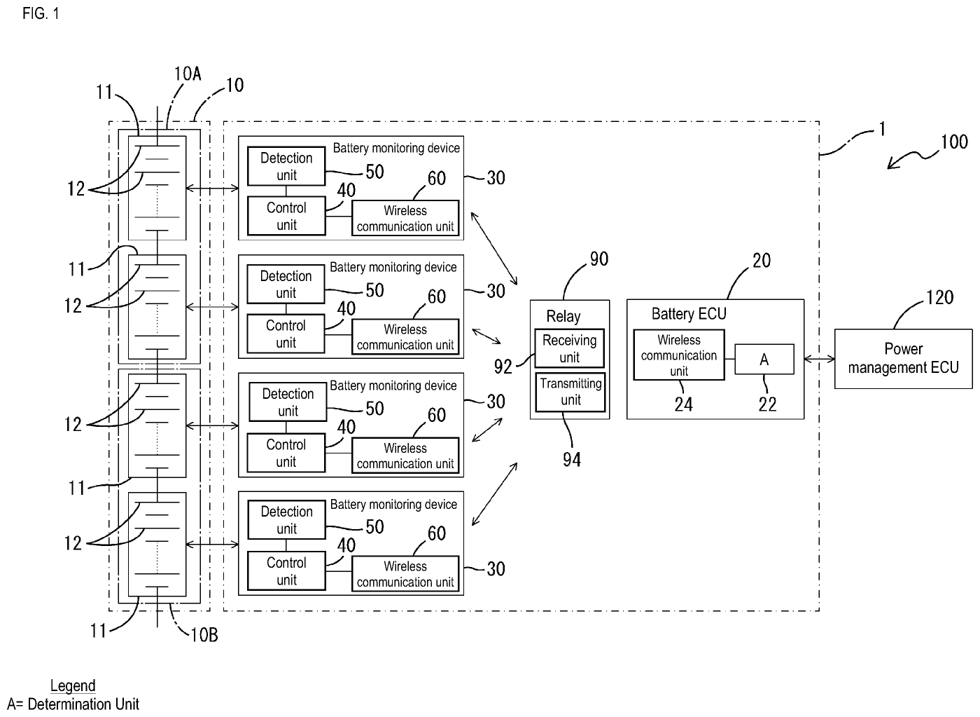

FIG. 1 shows the vehicular power supply system 100 in a simplified manner. The vehicular power supply system 100 shown in FIG. 1 is provided with a battery 10, a vehicular battery monitoring system 1 (hereinafter, referred to also as “battery monitoring system 1”) that monitors the battery 10, and a power management ECU 120 (Electric Control Unit) that can communicate with the battery monitoring system 1.

The battery 10 is, for example, a lithium-ion battery constituted by a plurality of battery cells 12, and is used as, for example, a power source that outputs electric power for driving an electromotive driving device (such as a motor) of a vehicle such as a hybrid vehicle or an electric vehicle (EV). The battery 10 is charged by a not-shown power-generating unit installed in the vehicle.

The battery 10 has a configuration in which a plurality of battery cells 12 configured as lithium-ion batteries are connected in series to each other to constitute one assembled battery 11, and a predetermined number of assembled batteries 11 are connected in series to each other to constitute one stack 10A, the stack 10A being housed in a case. Also, a plurality of thus-configured stacks 10A are connected in series to each other to constitute the battery 10 that can output a desired output voltage (for example, a few hundred V).

As shown in FIG. 1, the battery monitoring system 1 is provided with a plurality of vehicular battery monitoring devices 30 (hereinafter, referred to also as “battery monitoring devices 30”), a battery ECU 20 that serves as an external device, and a relay 90 that relays transmission of information therebetween, and the battery monitoring system 1 has a configuration in which the plurality of battery monitoring devices 30 wirelessly communicate with the battery ECU 20 (external device) via the relay 90. Note that the battery monitoring devices 30 are configured to be able also to wirelessly communicate with the battery ECU 20 without going through the relay 90.

The following will describe the battery monitoring devices 30 in detail.

In the example of FIG. 1, one battery monitoring device 30 is assigned to one of the assembled batteries 11 constituting the battery 10. Each battery monitoring device 30 is provided with a detection unit 50 that detects the voltage or temperature of the assigned assembled battery 11, a control unit 40 that performs various types of control such as control that corresponds to an instruction from the outside, and a wireless communication unit 60 that wirelessly communicates with the battery ECU 20, serving as an external device, via or directly without going through the relay 90.

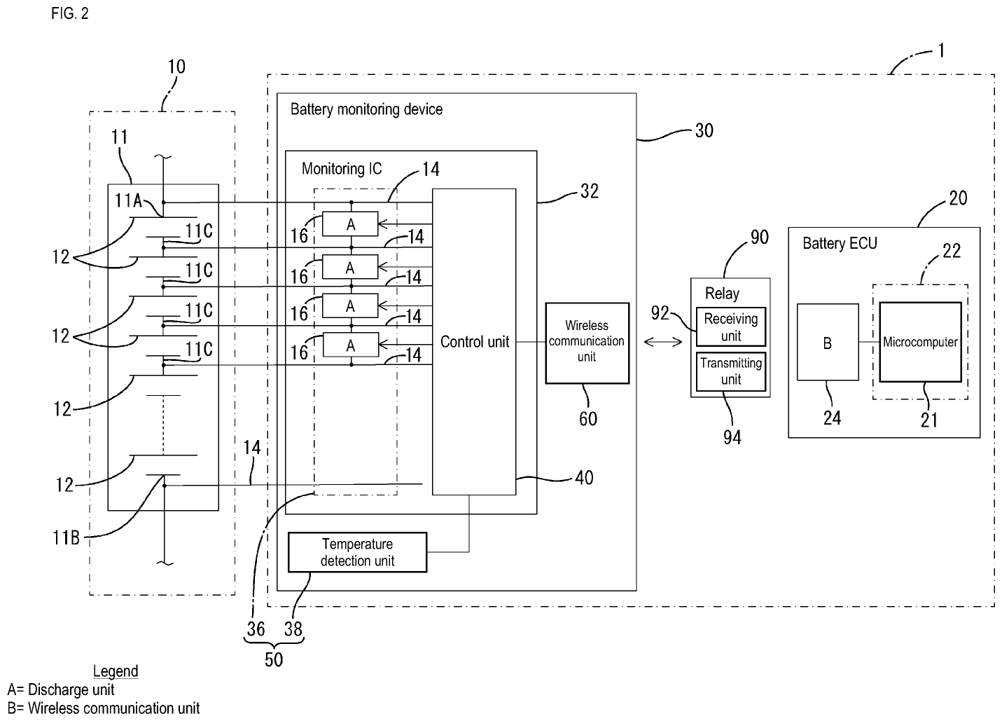

The control unit 40 is made of a microcomputer or another hardware circuit, and may be configured to be able to perform, at least when the wireless communication unit 60 receives an instruction from the outside, control that corresponds to this instruction. In the present configuration, as shown in FIG. 2, the control unit 40 and a detection/adjustment circuit unit 36 are integrated into a monitoring IC 32, for example.

In the example shown in FIG. 2, the control unit 40 is configured as a microcomputer that includes a CPU, a ROM, a RAM, and the like, and, for example, if a predetermined temperature detection instruction transmitted from the battery ECU 20 via or directly without going through the relay 90 has been received by the wireless communication unit 60, the control unit 40 functions to recognize the temperature or voltage of the battery 10 based on a signal transmitted from the detection unit 50, and perform response processing of transmitting information relating to the temperature or voltage of the battery 10 to the battery ECU 20. Furthermore, if predetermined cell balance instruction information transmitted from the battery ECU 20 via the relay 90 or directly without going through the relay 90 has been received by the wireless communication unit 60, the control unit 40 functions to perform cell balance processing to control the plurality of battery cells 12 to charge or discharge so that inter-terminal voltages (i.e. the voltages between the terminals) of the battery cells 12 are equalized based on detection results of the detection unit 50.

The detection unit 50 includes the detection/adjustment circuit unit 36 that functions as a voltage detection unit for detecting the voltage at a predetermined position of the battery 10, and a temperature detection unit 38 for detecting the temperature of the battery 10.

The detection/adjustment circuit unit 36 detects voltage information that specifies inter-terminal voltages of the battery cells 12 of the battery 10, in which the plurality of battery cells 12 are connected to each other. The detection/adjustment circuit unit 36 is provided with a plurality of voltage signal lines 14, and a plurality of discharge units 16 that are respectively connected in parallel with the plurality of battery cells 12. Note that, in FIG. 2, illustration of some of the battery cells 12 (unit battery) is omitted, and illustration of circuits that correspond to the omitted battery cells 12 is also omitted.

As shown in FIG. 2, the plurality of voltage signal lines 14 are electrically connected to inter-battery electrode portions 11C of the assembled battery 11, and end electrode portions 11A and 11B of the assembled battery 11, the assembled battery 11 being constituted by the plurality of battery cells 12 connected in series to each other. The electrode portion 11A is an electrode portion, at one end, of the assembled battery 11 and has the largest potential of the assembled battery 11. The electrode portion 11B is an electrode portion, at another end, of the assembled battery 11 and has the smallest potential of the assembled battery 11. The inter-battery electrode portions 11C are portions that are located between two of the battery cells 12 (unit batteries) connected in series to each other and in which the positive electrode on one side and the negative electrode on the other side are electrically connected to each other. The potentials of the plurality of inter-battery electrode portions 11C are larger toward the electrode portion 11A. The plurality of voltage signal lines 14 are signal lines through which analog signals indicating the potentials of the electrode portions 11A, 11B, and 11C are input to the control unit 40.

The control unit 40 can detect terminal voltages of the battery cells 12 (per unit battery) based on the analog voltage signals input through the respective voltage signal lines 14. Note that the control unit 40 includes an A/D converter that converts analog voltage signals input through the respective voltage signal lines 14 into digital signals. Because the control unit 40 can recognize the potentials of the electrode portions 11A, 11B, and 11C, the control unit 40 can also calculate inter-terminal voltages of the battery cells 12 (a voltage of each battery cell 12).

Note that current-limiting resistors may be provided on the respective voltage signal lines 14 to limit a current that flows into the control unit 40 from the battery cells 12 although, in FIG. 2, illustration of such current-limiting resistors and the like is omitted. Furthermore, it is desirable to arrange and connect, between voltage signal lines 14, a Zener diode (not shown) for clamping the voltage between voltage signal lines that occurs at the time of overvoltage, in parallel with each battery cell 12 (specifically, a Zener diode is connected in parallel with each battery cell 12 in such a manner that its cathode is connected to the positive electrode of the battery cell 12 and its anode is connected to the negative electrode thereof).

The temperature detection unit 38 is constituted by, for example, a well-known temperature sensor, and is arranged in such a manner that it is in contact with a surface of the assembled battery 11 or the stack 10A that is shown in FIG. 1 (the surface of the stack 10A being, for example, an outer surface or an inner surface of the case in which the assembled battery 11 is housed), or it is close thereto without being in contact therewith. The temperature detection unit 38 outputs a voltage value that indicates the temperature at the position at which it is arranged (that is, the temperature of the surface of the assembled battery 11 or the temperature in the vicinity of the surface) and inputs it to the control unit 40.

The monitoring IC 32 including the control unit 40 and the detection/adjustment circuit unit 36 serves as a cell balance circuit that makes the voltages or capacities of the battery cells 12 equal to each other. This cell balance circuit is, for example, a circuit that minimizes the variation in the voltages of the plurality of battery cells 12 as much as possible so that they are equal to each other. For example, it is conceivable to use a passive cell balance circuit that detects, from the assembled battery 11 assigned to a battery monitoring device 30, the battery cell 12 that has the smallest difference in potential between its positive electrode and negative electrode (inter-terminal voltage), and causes the other battery cells 12 to discharge to bring their voltages closer to the voltage of the detected battery cell 12 (that is, the battery cell 12 that has the smallest inter-terminal voltage).

The wireless communication unit 60 may be a circuit that performs wireless communication using a well-known wireless communication method, and the medium and frequency of wireless signals are not limited. For example, radio waves may be appropriately used as a medium, but infrared light or the like may also be used. Alternatively, electromagnetic waves may also be used instead.

The wireless communication unit 60 operates, when a wireless signal is transmitted from a wireless communication unit 24 of the battery ECU 20, so as to receive this wireless signal via the relay 90 or directly. For example, when a wireless signal transmitted from the wireless communication unit 24 of the battery ECU 20 is received by a receiving unit 92 of the relay 90 and is wirelessly transmitted by a transmitting unit 94, the wireless communication unit 60 operates so as to receive the wireless signal wirelessly transmitted from the relay 90. Furthermore, when a wireless signal is wirelessly transmitted from the wireless communication unit 24 of the battery ECU 20 directly to the wireless communication unit 60, the wireless communication unit 60 can receive the wireless signal.

The wireless communication unit 60 performs wireless transmission in accordance with control of the control unit 40, and operates to transmit at least information relating to battery 10 to the wireless communication unit 24 of the battery ECU 20. For example, if a temperature detection instruction is given from the battery ECU 20, the control unit 40 controls communication of the wireless communication unit 60, and the wireless communication unit 60 transmits information based on a detection result of the detection unit 50 (detection information indicating the voltage and temperature of the battery 10) to the battery ECU 20 using a wireless communication method. In this case, the detection information wirelessly transmitted from the wireless communication unit 60 is received at least by the receiving unit 92 of the relay 90, and is wirelessly transmitted to the battery ECU 20 by the transmitting unit 94 of the relay 90. Note that the detection information may also be wirelessly transmitted from the wireless communication unit 60 directly to the battery ECU 20.

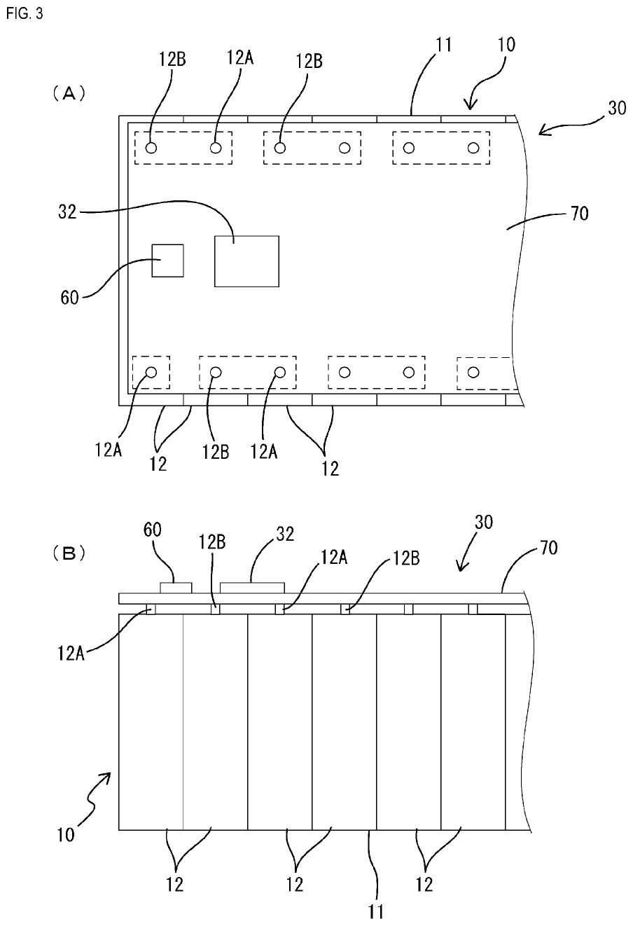

As shown in, for example, FIGS. 3(A) and 3(B), the thus-configured battery monitoring device 30 is attached to the battery 10. In the example of FIG. 3, the battery monitoring device 30 has a substrate portion 70 configured as a well-known printed-wiring board or the like, and is integrated with the assembled battery 11 with the substrate portion 70 directly fixed to the assembled battery 11. The substrate portion 70 may also be a rigid substrate or an FPC. The substrate portion 70 may also be, for example, a well-known busbar substrate. Furthermore, the substrate portion 70 may also be a mono-layer substrate or a multi-layer substrate. The above-described monitoring IC 32 and the wireless communication unit 60 are mounted on the substrate portion 70, and are integrated with the battery 10 via the substrate portion 70. Note that, in FIG. 3, illustration of the wiring pattern of the substrate portion 70 and other electronic components is omitted.

In the example of FIG. 3, the substrate portion 70 is fixed to terminal portions 12A and 12B (protruding portions serving as a positive electrode or a negative electrode) of the battery cells 12 constituting the assembled battery 11, and the above-described voltage signal lines 14 electrically connected to the terminal portions 12A and 12B are formed as the wiring pattern of the substrate portion 70. A terminal portion 12A is a protruding portion that serves as the positive electrode of a battery cell 12, and a terminal portion 12B is a protruding portion that serves as the negative electrode of the battery cell. Note that the structure shown in FIG. 3 is merely an example of an attachment structure, and the present disclosure is not limited to this example. For example, the substrate portion 70 does not need to be directly fixed to the battery 10 but may be indirectly attached thereto via another member.

The temperature sensor that constitutes the temperature detection unit 38 shown in FIGS. 1 and 2 may also be mounted at a position on the substrate portion 70 at which it is in contact with the battery 10 or a position at which it is in proximity to the battery 10. Alternatively, instead of being mounted on the substrate portion 70, the temperature sensor may be fixed to the battery 10 directly or indirectly via another member. If the temperature detection unit 38 is not mounted on the substrate portion 70, it is sufficient that the temperature detection unit 38 and the substrate portion 70 are electrically connected to each other via a wiring portion or the like.

The following will describe the battery ECU 20.

The battery ECU 20 shown in FIG. 1 corresponds to an example of an external device, and is configured to be able to receive information wirelessly transmitted from the wireless communication units 60 of the battery monitoring devices 30 or the relay 90, the battery ECU 20 being configured as an electronic control device that can perform various types of control. Furthermore, the battery ECU 20 can communicate with an external ECU shown in FIG. 1 (the power management ECU 120 of FIG. 1).

The battery ECU 20 includes the wireless communication unit 24, which performs wireless communication, and a determination unit 22, which performs various types of determination such as voltage abnormality determination. Specifically, as shown in FIG. 2, the battery ECU 20 includes the wireless communication unit 24 and a well-known microcomputer 21, the microcomputer 21 serving as the determination unit 22. The microcomputer 21 includes, for example, a CPU, a storage unit (such as a ROM and a RAM), an A/D converter, and the like, and can perform various types of control.

The thus-configured battery ECU 20 is able to wirelessly communicate with the battery monitoring devices 30 directly or via the relay 90, and can receive detection information (detection information indicating at least one of the voltage and the temperature of the battery) transmitted by the wireless communication units 60 of the battery monitoring devices 30. Furthermore, the battery ECU 20 may give various instructions to the battery monitoring devices 30 via wireless communication.

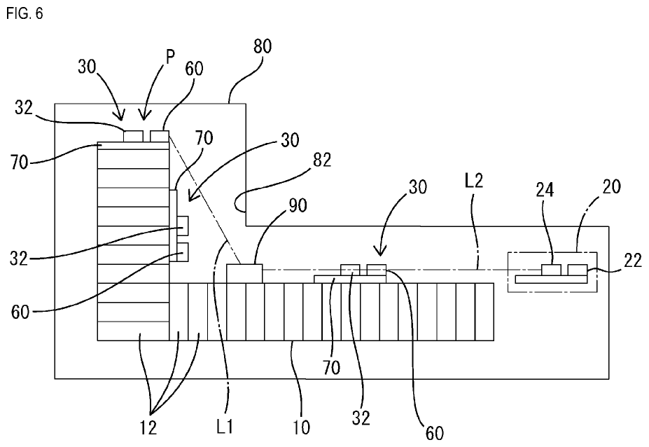

The thus-configured battery monitoring system 1 can be arranged, as shown in FIG. 6 for example, at a predetermined position within a vehicle while being housed together with the battery 10 in a metal housing 80. The metal housing 80 is formed as a metal case, and may be made of a well-known metal material of various types. As shown in FIG. 6, when the battery 10, the plurality of battery monitoring devices 30, the relay 90, and the battery ECU 20 are housed together in the same metal housing 80, it is possible to realize a more compact configuration that can suppress external impact, external noise interference, and the like using the metal housing 80, and wireless communication can be well performed within the metal housing 80.

In the battery monitoring system 1, an obstacle portion 82 including a metal material (in the example of FIG. 6, part of the metal housing 80) is arranged between at least one of the battery monitoring devices 30 (in FIG. 6, the battery monitoring device 30 at a position P) and the battery ECU 20 (external device). Also, the relay 90 is arranged in a positional relationship in which the obstacle portion 82 is not present between at least part of that battery monitoring device 30 (the battery monitoring device 30 at the position P) and at least part of the relay 90, and the obstacle portion 82 is not present between at least part of the battery ECU 20 and at least part of the relay 90. Specifically, the relationship is such that a straight line L1 can extend, without crossing the obstacle portion 82, between a position of the wireless communication unit 60 of the battery monitoring device 30 (the battery monitoring device 30 at the position P) and a position of the receiving unit 92 or the transmitting unit 94 of the relay 90, and a straight line L2 can extend, without crossing the obstacle portion 82, between a position of the wireless communication unit 24 of the battery ECU 20 and a position of the receiving unit 92 or the transmitting unit 94 of the relay 90.

In this way, it is desirable to arrange the metal housing 80 in which the battery 10 and the battery monitoring system 1 are housed, at a position within the vehicle that is apart from a noise generation source such as a motor or an alternator that serves as a traveling power source, and, for example, the metal housing 80 can be appropriately arranged at a position below a seat provided in the vehicle. Furthermore, if the motor, the alternator, or the like that serves as a traveling power source is arranged at a position close to the front end of the vehicle, the battery monitoring system 1 is preferably arranged at a position close to the back end of the vehicle. In contrast, if the motor, the alternator, or the like that serves as a traveling power source is arranged at a position close to the back end of the vehicle, the battery monitoring system 1 is preferably arranged at a position close to the front end of the vehicle. Note however that these examples are merely preferred examples, and the battery monitoring system 1 may be arranged at any position in the vehicle.

As shown in FIG. 1, the battery ECU 20 can communicate with the power management ECU 120 disposed on the outside with or without wires, but the power management ECU 120 may be disposed outside or inside of the above-described metal housing 80. For example, a configuration is also possible in which the battery ECU 20 housed in the metal housing 80 and the power management ECU 120 disposed outside of the metal housing 80 are communicably connected to each other via a communication line such as a CAN communication line, and can transmit and receive information to and from each other.

The following will describe the relay 90.

The relay 90 includes the receiving unit 92 that receives a wireless signal, and the transmitting unit 94 that transmits a wireless signal, the relay 90 having functions to receive a wireless signal from the outside at the receiving unit 92 and retransmit the received wireless signal from the transmitting unit 94.

The receiving unit 92 may be a circuit that can receive a wireless signal transmitted by a well-known wireless communication method, in which the medium and frequency of the wireless signal are not limited. Specifically, the receiving unit 92 is configured to at least be able to receive a wireless signal (a signal containing detection information and the like) transmitted from the wireless communication unit 60 of the battery monitoring device 30 or a wireless signal (a signal containing instruction information and the like) transmitted from the wireless communication unit 24 of the battery ECU. The transmitting unit 94 may be a circuit that can transmit a wireless signal using a well-known wireless communication method, in which the medium and frequency of the wireless signal are not limited. Specifically, the transmitting unit 94 is configured to be able to transmit a signal equivalent to the wireless signal (a signal containing detection information and the like) transmitted from the wireless communication unit 60 of the battery monitoring device 30, and a signal equivalent to the wireless signal (a signal containing instruction information and the like) transmitted from the wireless communication unit 24 of the battery ECU.

The following will describe an operation of the battery monitoring system 1.

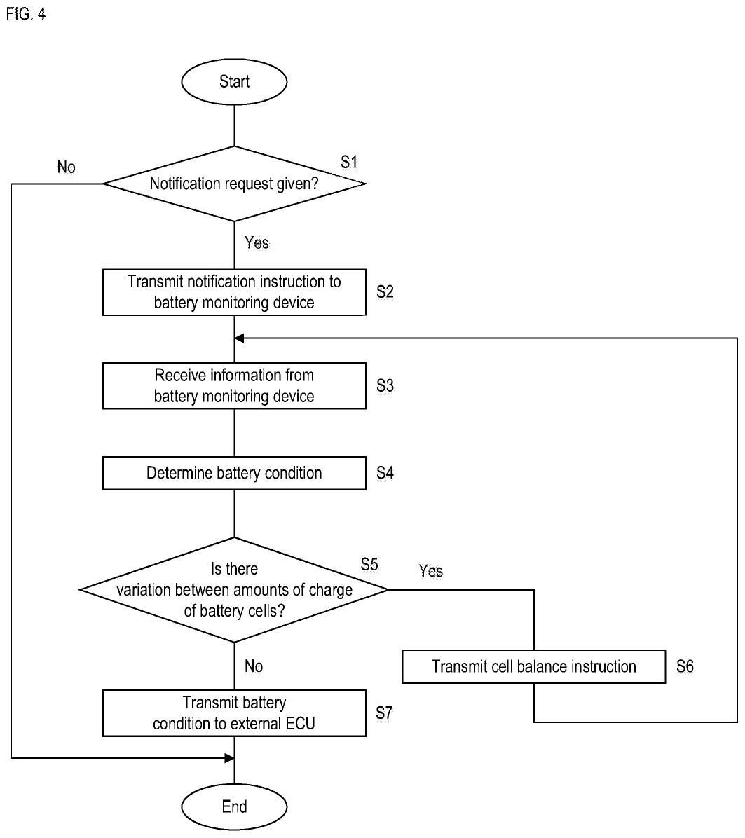

In the battery monitoring system 1, the battery ECU 20 performs control in a flow as shown in FIG. 4. The control of FIG. 4 is executed by, for example, the microcomputer 21 of the battery ECU 20, and the microcomputer 21 successively repeats the control of FIG. 4 in short time intervals, while an ignition switch is ON.

After the start of the control of FIG. 4, the battery ECU 20 determines whether or not a notification request has been made by the power management ECU 120. The power management ECU 120 is configured to transmit information indicating a predetermined notification request (request for notification of the condition of the battery 10) to the battery ECU 20 at a predetermined timing, and the battery ECU 20 determines, in step S1, whether or not a notification request has been made by the power management ECU 120. Note that the timing at which a notification request is transmitted from the power management ECU 120 to the battery ECU 20 may be, for example, a timing immediately after the ignition switch is turned ON from OFF, or may be another predetermined diagnosis timing.

If, in step S1, it is determined that a notification request has been made by the power management ECU 120, the battery ECU 20 wirelessly transmits, in step S2, predetermined notification instruction information to all of the battery monitoring devices 30 with which wireless communication is possible. The notification instruction information is instruction information that prompts the battery monitoring devices 30 to transmit a predetermined item of information. Note however that when, in step S2, notification instruction information is wirelessly transmitted, the instruction information is relayed such that it is received by the receiving unit 92 of the relay 90, and is retransmitted from the transmitting unit 94 of the relay 90 to the battery monitoring devices 30. Accordingly, upon receiving either notification instruction information transmitted from the transmitting unit 94 of the relay 90 or notification instruction information transmitted directly from the battery ECU 20, each battery monitoring device 30 can recognize the notification instruction information.

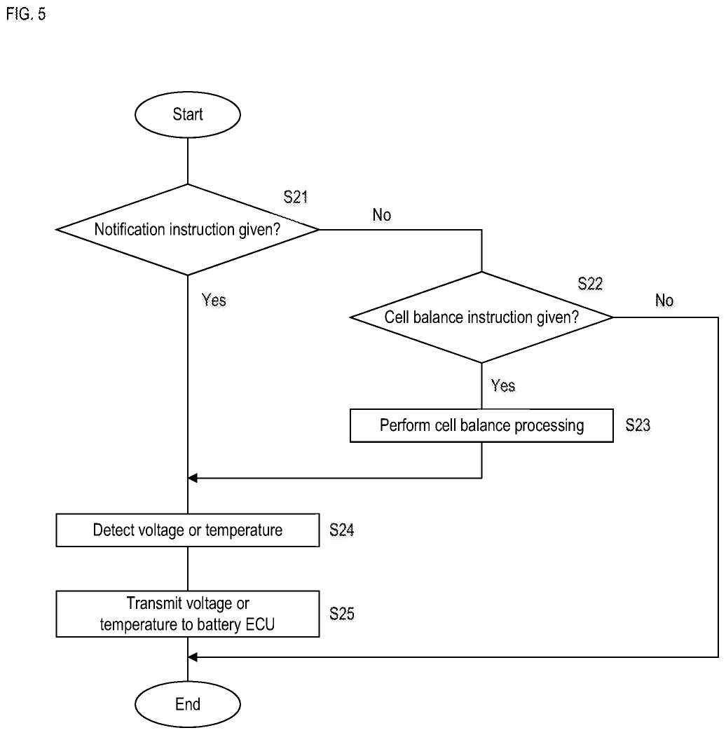

The battery monitoring devices 30 are configured to perform control in a flow as shown in FIG. 5. The control of FIG. 5 is executed by, for example, the control unit 40 of each battery monitoring device 30, and the control unit 40 successively repeats the control of FIG. 4 in short time intervals, while the ignition switch is ON.

After the start of the control of FIG. 5, the control unit 40 determines, in step S21, whether or not the above-described notification instruction has been given from the battery ECU 20 (specifically, whether or not notification instruction information transmitted from the battery ECU 20 or the relay 90 has been received). If, in step S21, it is determined that the notification instruction has been given from the battery ECU 20 (Yes, in step S21), the control unit 40 detects, in step S24, voltages and a temperature. Specifically, the control unit 40 calculates inter-terminal voltages of the battery cells 12 of the assembled battery 11 to which the corresponding battery monitoring device 30 is assigned, based on analog voltage values input through the voltage signal lines 14 shown in FIG. 2. Furthermore, the control unit 40 recognizes the temperature of the battery 10 (specifically, the temperature of the assigned assembled battery 11) based on a detection value input from the corresponding temperature detection unit 38.

After having detected the inter-terminal voltages of the battery cells 12 and the temperature of the assembled battery 11 in step S24, the control unit 40 wirelessly transmits, in step S25, information relating to them (detection information) to the battery ECU 20. Note however that when, in step S25, detection information is wirelessly transmitted, the detection information is relayed such that it is received by the receiving unit 92 of the relay 90 and is retransmitted from the transmitting unit 94 of the relay 90 to the battery ECU 20. Accordingly, upon receiving either detection information transmitted from the transmitting unit 94 of the relay 90 or notification instruction information transmitted directly from the battery monitoring devices 30, the battery ECU 20 can recognize the detection information.

Note that, in the above-described description, an example is taken in which, in step S24, inter-terminal voltages of the battery cells 12 constituting each assembled battery 11 and the temperature of the assembled battery 11 are detected, but it is also possible to calculate the overall voltage, internal resistance, capacity, or degradation level of the assembled battery 11, or the internal resistances, capacities, degradation levels, or the like of the battery cells 12, and transmit information indicating them, in step S25, to the battery ECU 20.

As shown in FIG. 4, after having transmitted the notification instruction information in step S2, the battery ECU 20 receives a response to this notification instruction information (information indicating the voltages and the temperature that is transmitted as a result of the battery monitoring device 30 performing the processing of step S25). Specifically, each of the plurality of battery monitoring devices 30 receives, directly or via the relay 90, the temperature information and the voltage information transmitted in step S25 of FIG. 5 (step S3).

After having received information from the battery monitoring devices 30 in step S3, the battery ECU 20 determines the condition of the battery 10 based on the information received in step S3. Specifically, the determination unit 22 (that is, the microcomputer 21) calculates the overall voltage of the battery 10 (battery voltage) based on the information transmitted from the plurality of battery monitoring devices 30. For example, the overall voltage of the battery 10 can be calculated by integrating the overall voltages of the assembled batteries 11 to which the battery monitoring devices 30 are respectively assigned. Alternatively, the overall voltage of the battery 10 can be calculated by integrating the inter-terminal voltages of all of the battery cells 12. Also, the determination unit 22 determines whether or not the thus-calculated overall voltage of the battery 10 (battery voltage) is in an overcharge condition in which it exceeds a predetermined first threshold, and whether or not the battery voltage is in an overdischarge condition in which it is less than a predetermined second threshold value, which is lower than the first threshold. Furthermore, the determination unit 22 determines, based on the temperature information obtained from the battery monitoring devices 30, whether or not the temperature of any of the assembled batteries 11 is in an overtemperature condition in which it exceeds a predetermined temperature threshold. Thus, the determination unit 22 determines whether or not the voltage and the temperature of the battery 10 are abnormal based on the detection information received by the wireless communication unit 24.

After step S4, it is determined, with respect to each of the assembled batteries 11, whether or not the variation between the inter-terminal voltages of the plurality of battery cells 12 is within a predetermined value (step S5). For example, it is determined based on the information received from the battery monitoring devices 30 whether or not, in any of the assembled batteries 11, the difference in inter-terminal voltage between the battery cell 12 with the largest inter-terminal voltage and the battery cell 12 with the smallest inter-terminal voltage exceeds a predetermined value, and if, in any assembled battery 11, this difference exceeds the predetermined value (Yes in step S5), cell balance instruction information is transmitted, in step S6, to the battery monitoring device 30 to which this assembled battery 11 is assigned. The cell balance instruction information refers to information that contains an instruction to instruct the battery monitoring device 30 to execute cell balance processing, and is, for example, a command specified by predetermined information. Also in this case, when cell balance instruction information is wirelessly transmitted in step S6, the cell balance instruction information is relayed such that it is received by the receiving unit 92 of the relay 90, and is retransmitted from the transmitting unit 94 of the relay 90 to the battery monitoring device 30. Accordingly, upon receiving either cell balance instruction information transmitted from the transmitting unit 94 of the relay 90 or cell balance instruction information transmitted directly from the battery ECU 20, the battery monitoring device 30 can recognize the cell balance instruction information.

As shown in FIG. 5, the battery monitoring device 30 determines, in step S22 of the processing shown in FIG. 5 that is repeated in short time intervals, whether or not a cell balance instruction has been given, and if cell balance instruction information, instead of the above-described notification instruction information, has been received from the battery ECU 20 or the relay 90 (No in step S21 and Yes in step S22), the battery monitoring device 30 performs cell balance processing in step S23. Specifically, the battery monitoring device 30 to which the cell balance instruction information was given causes its detection/adjustment circuit unit 36 to operate so that, of the plurality of battery cells 12 constituting the assembled battery 11 assigned to this battery monitoring device 30, the battery cells 12, other than the battery cell 12 with the lowest output voltage, discharge to bring their output voltages closer to the lowest output voltage. The discharge units 16 for causing the respective battery cells 12 to discharge are connected to the detection/adjustment circuit unit 36, and the control unit 40 controls operations of the discharge units 16 to equalize and bring the inter-terminal voltages of all of the battery cells 12 of the assigned assembled battery 11 into the same range.

When having performed the cell balance processing in step S23 in FIG. 5, the battery monitoring device 30 performs the above-described processing of step S24 again, and detects the inter-terminal voltages of the battery cells 12 and the temperature of the assembled battery 11 that are subjected to the cell balance processing in the assigned assembled battery 11. Then, processing in step S25 is executed, and the items of information detected in step S24 are transmitted to the battery ECU 20.

Note that, if cell balance instruction information is transmitted selectively to any of the battery monitoring devices 30 from the battery ECU 20, the cell balance instruction information may preferably contain address information that indicates the address of the target battery monitoring device 30. When such a method is used, it is preferable that each battery monitoring device 30 has stored in advance its own address information, and the battery monitoring device 30 determines, based on the address information contained in the cell balance instruction information, whether or not the received cell balance instruction information is an instruction given to the battery monitoring device 30 itself. In other words, the battery monitoring device 30 only needs to execute the processing in step S23 when having received cell balance instruction information containing information indicating its own address. Note that a configuration is also possible in which, without using such a method, cell balance instruction information is given to all of the battery monitoring devices 30 from the battery ECU 20.

When having transmitted the cell balance instruction information in step S6 in FIG. 4, the battery ECU 20 receives, in step S3, information transmitted from the battery monitoring device 30 to which this cell balance instruction information was given, and performs the processing from step S4 onwards based on this information. Note that, in this case, as information relating to the assembled battery 11 assigned to the battery monitoring device 30 to which no cell balance instruction information was given (information relating to the inter-terminal voltages of the battery cells 12 and the temperature of the assembled battery 11), already obtained information may be used.

In the determination in step S5 in FIG. 4, if it is determined that, in all of the assembled batteries 11, the variations between the inter-terminal voltages of the plurality of battery cells 12 are within a predetermined value, the battery ECU 20 transmits a battery condition to the external ECU (power management ECU 120) in step S7. Specifically, the battery ECU 20 transmits, based on the previous determination result in step S4, information that indicates whether or not the battery voltage is in the overcharge condition in which it exceeds the predetermined first threshold, information that indicates whether or not the battery voltage is in the overdischarge condition in which it is less than the second threshold value, information that indicates whether or not the temperature of any of the assembled batteries 11 is in the overtemperature condition in which it exceeds a predetermined temperature threshold, and the like, to the power management ECU 120. Note that, in addition, various types of information such as SOC, SOH, or the internal resistance of the battery 10 may also be transmitted, for example.

Hereinafter, examples of effects of the present configuration will be described.

Since the above-described battery monitoring devices 30 and battery monitoring system 1 can transmit detection information based on detection results of the detection units 50 (information indicating at least one of the voltage and the temperature of the battery) via wireless communication, it is possible to effectively reduce the number of wires. Furthermore, when the detection information is transmitted to the battery ECU 20 (external device), the detection information can at least be relayed by the relay 90 and then transmitted, and thus the information can be better transmitted as long as the battery ECU 20 is arranged at a position at which wireless transmission is possible from the relay 90.

If predetermined instruction information is wirelessly transmitted from the battery ECU 20 (external device), the receiving unit 92 of the relay 90 functions to receive this instruction information. The transmitting unit 94 of the relay 90 functions to wirelessly transmit the instruction information upon the instruction information being received by the receiving unit 92. Each battery monitoring device 30 includes a control unit 40 configured to perform control that corresponds to an instruction given from the outside. The wireless communication unit 60 functions to receive the instruction information when the instruction information is wirelessly transmitted from the transmitting unit 94. The control unit 40 performs control that corresponds to the instruction information upon the instruction information being received by the wireless communication unit 60.

According to the above-described configuration, it is possible to realize a battery monitoring system 1 in which the battery monitoring device 30 can perform control that corresponds to an instruction given from the battery ECU 20 (external device), with a configuration in which the number of wires can be reduced and information can be well transmitted.

If predetermined notification instruction information is wirelessly transmitted from the battery ECU 20 (external device), the receiving unit 92 of the relay 90 functions to receive this notification instruction information. The transmitting unit 94 of the relay 90 functions to wirelessly transmit the notification instruction information upon the notification instruction information being received by the receiving unit 92. When the notification instruction information is received by the wireless communication unit 60, the control unit 40 causes the wireless communication unit 60 to wirelessly transmit the detection information that indicates at least one of the voltage and the temperature of the battery 10 to the relay 90.

According to the above-described configuration, it is possible to realize a battery monitoring system 1 in which information detected by the battery monitoring device 30 (detection information indicating at least one of the voltage and the temperature of the battery 10) can be transmitted to the battery ECU 20 in accordance with an instruction given from the battery ECU 20 (external device), with a configuration in which the number of wires can be reduced and information can be well transmitted.

If predetermined cell balance instruction information is wirelessly transmitted from the battery ECU 20 (external device), the receiving unit 92 of the relay 90 functions to receive this cell balance instruction information. The transmitting unit 94 of the relay 90 functions to wirelessly transmit the cell balance instruction information upon the cell balance instruction information being received by the receiving unit 92. The detection unit 50 can detect, with respect to the battery 10 in which the plurality of battery cells 12 are connected to each other, voltage information that specifies the inter-terminal voltages of the battery cells 12. When the cell balance instruction information is received by the wireless communication unit 60, the control unit 40 causes the plurality of battery cells 12 to charge or discharge so that the inter-terminal voltages of the battery cells 12 are equalized, based on detection results of the detection unit 50.

According to the above-described configuration, it is possible to realize the battery monitoring system 1 in which the battery monitoring device 30 can perform cell balance control to equalize the inter-terminal voltages of the plurality of battery cells 12 in accordance with an instruction given from the battery ECU 20 (external device), with a configuration in which the number of wires can be reduced and information can be well transmitted.

In the battery monitoring system 1, the obstacle portion 82 that contains a metal material (part of the metal housing 80 in the example of FIG. 6) is arranged between the at least one of the battery monitoring devices 30 and the battery ECU 20 (external device). Also, the relay 90 is arranged in a positional relationship such that the obstacle portion 82 is not present between this battery monitoring device 30 and the relay 90, and the obstacle portion 82 is not present between the battery ECU 20 and the relay 90.

With this measure, it is possible to well perform wireless communication in an environment in which wireless communication medium is likely to be impaired when wireless transmission is performed directly from the battery monitoring devices 30 to the battery ECU 20 (external device).

The battery monitoring devices 30 and the relay 90 are arranged in the metal housing 80 in which the battery 10 and the battery ECU 20 (external device) are housed.

With this measure, the metal housing 80 can be used to prevent external impact, external radio wave interference, or the like, and in the metal housing 80, the number of wires is reliably reduced and communication between the battery monitoring devices 30 and the battery ECU 20 (external device) is likely to be performed well.

The battery monitoring system 1 includes the plurality of battery monitoring devices 30. The relay 90 functions to receive items of information wirelessly transmitted from the plurality of battery monitoring devices 30, and wirelessly transmit the received items of information to the battery ECU 20 (external device).

According to the above-described configuration, it is possible to realize a system in which a plurality of battery monitoring devices 30 can communicate with a common battery ECU 20 (external device), with a configuration in which the number of wires can be reduced and information can be well transmitted. Particularly, if a plurality of battery monitoring devices 30 are arranged in a distributed manner, and wires are provided so that communication is possible between the respective battery monitoring devices 30 and the battery ECU 20, the larger number of wires are required, and thus an increase in size and weight is inevitable. In contrast thereto, according to the above-described configuration, when the plurality of battery monitoring devices 30 communicate with the common battery ECU 20, it is possible to significantly reduce the number of wires, and thus larger effects of reductions in size and weight can be achieved.

### OTHER EMBODIMENTS

The present disclosure is not limited to the embodiment described with reference to the description above and the drawings, and the technical scope of the present disclosure encompasses, for example, the following embodiments. Furthermore, the above-described embodiment and below-described embodiments may be combined with each other unless they contradict each other.

In Embodiment 1, an example of cell balance processing is taken, but the cell balance processing may also be performed using a well-known method. In the example of Embodiment 1, individual battery cells 12 are configured to be able to discharge, and their inter-terminal voltages are equalized by controlling discharge of the battery cells 12, but a configuration is also possible in which individual battery cells 12 are able to discharge and charge, and their inter-terminal voltages are equalized by controlling discharge and charge of the battery cells 12.

In Embodiment 1, one battery monitoring device 30 is assigned to one assembled battery 11, but one battery monitoring device 30 may also be assigned to a plurality of assembled batteries 11. Alternatively, one assembled battery 11 may also be divided into a plurality of areas, and one battery monitoring device 30 may be assigned to each of the areas.

In Embodiment 1, an example is taken in which the substrate portion 70 is directly fixed to the battery 10, but the substrate portion 70 may also be fixed indirectly to the battery 10 via another member.

In Embodiment 1, the battery ECU 20 is taken as an example of the external device, but the external device is not limited to the battery ECU 20 as long as it is an onboard electronic device arranged outside of the battery monitoring device 30.

In Embodiment 1, an example is taken in which a battery monitoring device 30 is assigned to an assembled battery 11 including an assembly of a plurality of battery cells 12, but a configuration is also possible in which the battery monitoring device 30 is attached to one battery (a single battery), and the battery voltage or the battery temperature of this battery is transmitted to the battery ECU 20 using a wireless communication method, directly or via the relay 90.

In Embodiment 1, an example is taken in which the battery monitoring system 1 is housed in a metal housing, but it does not need to be housed in the metal housing.

In Embodiment 1, an example is taken in which a wireless signal received by the receiving unit 92 of the relay 90 is wirelessly transmitted by the transmitting unit 94. The wireless signal received by the receiving unit 92 may also be amplified and then wirelessly transmitted by the transmitting unit 94.

1. (canceled)

2. (canceled)

3. (canceled)

4. (canceled)

5. A vehicular battery monitoring system comprising:
a battery monitoring device provided with a detection unit configured to detect at least one of a voltage at a predetermined position of a battery installed in a vehicle and a temperature of the battery, and a wireless communication unit configured to wirelessly transmit detection information that indicates at least one of the voltage and the temperature of the battery based on a detection result of the detection unit; and
a relay provided with a receiving unit configured to receive the detection information transmitted from the wireless communication unit of the battery monitoring device, and a transmitting unit configured to wirelessly transmit the detection information received by the receiving unit to an external device,
wherein the battery monitoring device and the relay are arranged in a metal housing in which the battery and the external device are housed,
part of the metal housing is arranged as an obstacle portion between the battery monitoring device and the external device, and the relay is arranged in a positional relationship such that there is a space without the obstacle portion between the battery monitoring device and the relay, and there is a space without the obstacle portion between the external device and the relay.

6. The vehicular battery monitoring system according to claim 5,
wherein, if predetermined instruction information is wirelessly transmitted from the external device, the receiving unit of the relay receives the instruction information,
the transmitting unit of the relay wirelessly transmits the instruction information upon the instruction information being received by the receiving unit,
the battery monitoring device includes a control unit configured to perform control that corresponds to an instruction given from the outside,
the wireless communication unit receives the instruction information when the instruction information is wirelessly transmitted from the transmitting unit, and
the control unit performs control that corresponds to the instruction information upon the instruction information being received by the wireless communication unit.

7. The vehicular battery monitoring system according to claim 6,
wherein, if predetermined notification instruction information is wirelessly transmitted from the external device, the receiving unit of the relay receives the notification instruction information,
the transmitting unit of the relay wirelessly transmits the notification instruction information upon the notification instruction information being received by the receiving unit,
when notification instruction information is received by the wireless communication unit, the control unit causes the wireless communication unit to wirelessly transmit the detection information indicating at least one of the voltage and the temperature of the battery to the relay.

8. The vehicular battery monitoring system according to claim 6,
wherein, if predetermined cell balance instruction information is wirelessly transmitted from the external device, the receiving unit of the relay receives the cell balance instruction information,
the transmitting unit of the relay wirelessly transmits the cell balance instruction information upon the cell balance instruction information being received by the receiving unit,
the detection unit detects, with respect to the battery in which a plurality of battery cells are connected to each other, voltage information that specifies inter-terminal voltages of the battery cells, and
when the cell balance instruction information is received by the wireless communication unit, the control unit causes the plurality of battery cells to charge or discharge so that the inter-terminal voltages of the battery cells are equalized, based on detection results of the detection unit.

9. (canceled)

10. (canceled)

11. The vehicular battery monitoring system according to claim 5, comprising
a plurality of battery monitoring devices,
wherein the relay is configured to receive items of information wirelessly transmitted from the plurality of battery monitoring devices and wirelessly transmit the items of information to the external device.

12. The vehicular battery monitoring system according to claim 5, comprising the external device.

13. The vehicular battery monitoring system according to claim 7,
wherein, if predetermined cell balance instruction information is wirelessly transmitted from the external device, the receiving unit of the relay receives the cell balance instruction information,
the transmitting unit of the relay wirelessly transmits the cell balance instruction information upon the cell balance instruction information being received by the receiving unit,
the detection unit detects, with respect to the battery in which a plurality of battery cells are connected to each other, voltage information that specifies inter-terminal voltages of the battery cells, and
when the cell balance instruction information is received by the wireless communication unit, the control unit causes the plurality of battery cells to charge or discharge so that the inter-terminal voltages of the battery cells are equalized, based on detection results of the detection unit.

14. The vehicular battery monitoring system according to claim 6, comprising
a plurality of battery monitoring devices,
wherein the relay is configured to receive items of information wirelessly transmitted from the plurality of battery monitoring devices and wirelessly transmit the items of information to the external device.

15. The vehicular battery monitoring system according to claim 7, comprising
a plurality of battery monitoring devices,
wherein the relay is configured to receive items of information wirelessly transmitted from the plurality of battery monitoring devices and wirelessly transmit the items of information to the external device.

16. The vehicular battery monitoring system according to claim 8, comprising
a plurality of battery monitoring devices,
wherein the relay is configured to receive items of information wirelessly transmitted from the plurality of battery monitoring devices and wirelessly transmit the items of information to the external device.

17. The vehicular battery monitoring system according to claim 6, comprising the external device.

18. The vehicular battery monitoring system according to claim 7, comprising the external device.

19. The vehicular battery monitoring system according to claim 8, comprising the external device.

20. The vehicular battery monitoring system according to claim 11, comprising the external device.
